(19) United States
(12) Patent Application Publication
(10) Pub. No.: US 2025/0054868 A1
(43) Pub. Date: Feb. 13, 2025

(54) POWER MODULE BRIDGE AND METHOD FOR MANUFACTURING IT

(71) Applicant: Robert Bosch GmbH, Stuttgart (DE)

(72) Inventor: Irfan Aydogmus, Nuertingen (DE)

(21) Appl. No.: 18/785,011

(22) Filed: Jul. 26, 2024

(30) Foreign Application Priority Data
Aug. 11, 2023 (DE) 10 2023 207 742.6

(51) Int. Cl. H01L 23/538; H01L 21/56; H01L 23/00; H01L 23/053; H01L 23/24; H01L 23/31; H01L 23/36; H01L 25/00; H01L 25/065; H02K 11/33

(52) U.S. Cl. CPC H01L 23/5385; H01L 23/24; H01L 24/48; H01L 25/0655; H01L 25/50; H02K 11/33; H01L 21/561; H01L 23/053; H01L 23/3107; H01L 23/36; H01L 23/5387; H01L 24/85; H01L 2224/48225; H01L 2224/85

(57) ABSTRACT

A power module bridge. The power module bridge includes: one or more power modules each including: one or more circuit carriers, one or more semiconductor switches, one or more connection boards, one or more flexible printed circuit boards, and. one or more spacers; a gate circuit board; a frame with lateral boundaries and with an upwardly and/or downwardly exposed region, wherein a volume enclosed by the frame is filled with a gel; and one or more connecting elements, wherein one or more circuit carriers, one or more semiconductor switches, one or more spacers, and one or more connection boards are connected to one another via a sintered connection.

### CROSS REFERENCE

The present application claims the benefit under 35 U.S.C. § 119 of German Patent Application No. DE 10 2023 207 742.6 filed on Aug. 11, 2023, which is expressly incorporated herein by reference in its entirety.

### FIELD

The present invention relates to a power module bridge, in particular a power module bridge such as a power module B6 bridge for converting a direct current into an alternating current. The present invention also relates to one or more power modules without a molded body and their integration into a power module bridge and gelling the one or more power modules inside the power module bridge.

### BACKGROUND INFORMATION

In the related art, power modules that are installed in a power module bridge, for example, are additionally molded. During molding, the power module is embedded in a solid protective housing, for example made of plastic (molding compound). The purpose of the molding compound is to encase and protect the interior of the power module. However, these encasements of the power module with molding compound are not particularly resistant to cracking.

German Patent Application No. DE 11 2017 004 390 T5 describes a power module that has the following features: an insulating substrate with a front side to which a power semiconductor element is attached; a base plate which is connected to a rear side of the insulating substrate; a housing which is attached to the base plate and encloses the insulating substrate; a cover which is attached to the housing and forms a sealed region; and a silicone gel which serves as a filling element and fills the entire sealed region and has internal stress that acts as compressive stress.

### SUMMARY

According to the present invention, a power module bridge, such as a power module B2 or a power module B6 bridge according to a first aspect is provided. According to an example embodiment of the present invention, the power module bridge includes:
one or more power modules, wherein the one or more power modules comprise:
   i. one or more circuit carriers which include at least three layers of material, wherein a middle circuit carrier layer includes an insulating material, a first outer circuit carrier layer and a second outer circuit carrier layer include an electrically conductive material, wherein the outer layers are configured as one or more conductor structures,
   ii. one or more semiconductor switches,
   iii. one or more connection boards including at least three layers of material, wherein a middle connection board layer includes an insulating material, a first outer connection board layer and a second outer connection board layer include an electrically conductive material, wherein the one or more connection boards comprise(s) one or more contact elements,
   iv. one or more flexible printed circuit boards and
   v. one or more spacers,
a gate circuit board,
a frame with lateral boundaries and with an upwardly and/or downwardly exposed region, wherein a volume enclosed by the frame is filled with a gel, and
one or more connecting elements,
   wherein one or more circuit carriers, one or more semiconductor switches, one or more spacers and one or more connection boards are connected to one another via a sintered connection.

The solution according to the present invention presents a power module bridge. A power module bridge is an electronic circuit in which power electronics, such as power modules, are used. The power module bridges are used in a variety of applications such as engine controls, power converter circuits, switched-mode power supplies and power converters. The solution according to the present invention is particularly suitable for power converters within an electric vehicle, for example. Here, a power converter converts direct current (DC) to alternating current (AC).

According to an example embodiment of the present invention, a circuit carrier is a component of the power module. A circuit carrier can, for example, include a plurality of layers of material, in which case the outer layers contain an electrically conductive layer, for instance, and the inner layer contain an electrically non-conductive material. A conductive layer can be used to electrically connect various power electronic components, for example. Effective thermal management of the power electronics can moreover be made possible by integrating an electrically non-conductive layer, for instance. The integration of conductive and non-conductive layers can, for example, create heat dissipation paths to dissipate heat from power components. The outer layers of a circuit carrier can be configured as conductor structures, for example, in which case the number and shape of a conductor structure can vary depending on the power module. A power structure includes a conductive material that is applied to an insulating circuit carrier and serves to enable the flow of electrical current between the components and ensure efficient energy transfer.

According to an example embodiment of the present invention, a connection board is likewise a component of the power module. A connection board can have a multi-layer structure, for example, in which case the outer layers include an electrically conductive layer, for instance, and the inner layer includes an electrically non-conductive material. A conductive layer can be used to electrically connect various power electronic components, for example. Effective thermal management of the power electronics can moreover be made possible by integrating an electrically non-conductive layer, for instance. The integration of conductive and non-conductive layers can create heat dissipation paths for the heat dissipation from power components.

In the context of the present invention, a power module includes one or more spacers which are disposed between printed circuit boards, semiconductor switches and circuit carriers, for example. These spacers can include an insulating material and minimize electrical and technical problems. Integrating the spacers into a power module makes it possible to avoid short circuits. The integration of spacers moreover provides efficient heat dissipation, which leads to improved performance and reliable function of the power module. The spacers are furthermore connected to semiconductor switches, printed circuit boards and circuit carriers by means of sintering, for example. One advantage of sintering, for example, is that there is no need for additional fastening elements such as screws, adhesives or weld seams, which eliminates weak points or points of failure associated with the use of such fastening elements. Furthermore, sintering involves an even distribution of stress over the components of the power module because the stress is distributed evenly over the entire joining surface. This makes it possible to reduce the concentration of stresses and improve the overall stability of a fastener.

Within the meaning of the present invention, a power module bridge includes a gate circuit board. A gate circuit board is a component of the power module bridge and is, for example, a separate printed circuit board to which all of the components of the power module bridge are attached. Within the meaning of the present invention, a power module bridge also includes a frame, wherein the frame comprises a solid material, such as plastic. A frame according to the present invention ensures stable mounting and positioning of the power modules on a gate circuit board, and this frame also provides a physical barrier to protect the components of the power module bridge from damage and to extend the service life of the power module. The frame according to the present invention furthermore provides an enclosed volume that is filled with a gel mass.

In accordance with an example embodiment the present invention, a power module bridge includes one or more flexible printed circuit boards. A flexible printed circuit board, also referred to as a flex PCB (flexible printed circuit board), is an electronic component that includes flexible substrate material which contains the conductor tracks and the electrical connections. The substrate material consists of plastic, polyamide or other flexible materials, for instance. Due to its flexibility and bendability, the flexible printed circuit board can be adapted to different shapes and surfaces and can be integrated into power module bridges in a space-saving manner.

The solution according to the present invention creates a particularly advantageous structure of the power module bridge. The power modules installed inside the power module bridge are not encased with a molding compound as in other possible state-of-the-art structures; the power module has instead been covered with a gel without such an additional encasement.

In an advantageous further development of the power module bridge provided according to the present invention, a power module bridge is proposed, in which one or more conductor tracks of the one or more flexible printed circuit boards are attached to the contact elements and a portion of a flexible printed circuit board is attached to one or more connection boards with a material-locking connection, and the remaining portion of the flexible printed circuit board is aligned perpendicular to the attached portion of the flexible printed circuit board.

According to an example embodiment of the present invention, one or more flexible printed circuit boards include one or more conductor tracks, wherein these conductor tracks are connected to the contact elements of the power module. The portion of the flexible printed circuit board adjoining the contact elements is then connected to the power module in a material-locking manner.

The portion of the flexible printed circuit board adjoining the adhesion point can be aligned perpendicular, for example 90°, to the adhesion point.

In a further development of the power module bridge according to the present invention, it is proposed that the one or more power modules are positioned inside a frame.

In a further development of the power module bridge provided according to the present invention, a power module bridge is proposed, in which a frame has a variable frame height, wherein a variable frame height is 12 mm, preferably 2 to 7 mm, particularly preferably 4 to 5 mm.

According to an example embodiment of the present invention, a variable frame height is provided, wherein the frame height is based on the height of the power modules installed in the frame, because the frame height forms the enclosed volume for filling the gel. Following the provided solution, the frame height is higher than the power module and components, such as bonding wires and semiconductor circuits, connected to the power module.

In a further development of the power module bridge according to an example embodiment of the present invention, a power module bridge is provided, wherein the volume enclosed by the frame is filled with a gel such that one or more power modules are completely covered with the gel.

An enclosed volume of a frame refers to the region of the bounding structures of the frame. It includes the space bounded by the outer dimensions of the frame, including the surfaces of the power modules, the connecting elements, the bonding wires and other electronic components of the power modules. An enclosed volume includes at least one open side.

In a further development of the power module bridge according to the present invention, a power module bridge is provided, in which the gel is a silicone gel.

A silicone gel is a semi-solid material comprising a silicone polymer network suspended in a liquid or viscous medium. In the context of the use of a power module bridge according to the present invention, the silicone gel exhibits excellent temperature resistance; it tolerates thermal stresses at elevated temperatures very well without compromising structural strength or deforming. Among other things, unlike molding compound, it exhibits high elasticity and flexibility and is therefore able to absorb and distribute thermal stresses without tearing or cracking. A silicone gel also has a lower coefficient of thermal conductivity, which improves the insulation and limitation of local temperature differences.

According to an example embodiment of the present invention, a method for manufacturing a power module bridge according to the present invention including one or more power modules, a gate circuit board, a frame, a gel, and one or more connecting elements according to one of the preceding configurations of the power module bridge according to the present invention is provided, wherein the method comprises the following steps:
a. providing one or more power modules,
b. attaching the one or more flexible printed circuit boards to the one or more power modules,
c. mounting the one or more power modules to the gate circuit board,
d. mounting a frame to the gate circuit board around the one or more power modules,
e. mounting the one or more connecting elements on the one or more power modules, wherein the one or more connecting elements are mounted such that each connecting element is also attached to the gate circuit board via the frame, and
f. filling the inner region of the frame with a gel.

The provided method according to the present invention makes it possible to integrate the power module bridge into various embodiments, such as electric vehicles. The method furthermore achieves a particularly advantageous structure of a power module bridge, in which the power module bridge is designed in such a way that thermomechanical stress on the components of the power module bridge is reduced by not encasing a power module with molding compound and by surrounding the electronic components inside a frame with gel. This reduces the occurrence of material fatigue and/or crack formation, for example, which leads to a longer service life of the power module bridge. The occurring temperature differences can also be reduced by the targeted use of cooling measures, for example, which results in an improvement of the structural integrity and the service life.

The method according to the present invention is particularly well-suited for efficient heat dissipation, for example, because a gel mass exhibits thermal properties that enable efficient heat dissipation from the encapsulated components. This makes it possible to optimally maintain the operating temperature of a power module bridge, for example. The use of a gel also provides an effective protective layer for the encased power module components against harmful environmental influences such as moisture, dust, dirt or chemical substances. The gel mass can furthermore have a shock and vibration damping effect by acting as a padding and protecting the encased power module components from mechanical stresses. This is particularly advantageous in applications in which electronic components are subjected to vibrations or shocks, such as in the automotive industry. Compared to a rigid encasement material, a gel mass also provides greater flexibility and adaptability to the shape and size of the encased power module components. Moreover, due to the lower material requirements and the less complex processing steps, it is more cost-effective to use a gel mass instead of a rigid encasement.

In an advantageous further development of the method according to the present invention for manufacturing a power module bridge, it is provided that the one or more power modules be attached to a gate circuit board by means of a material-locking connection.

In a further advantageous further development of the method according to the present invention for manufacturing a power module bridge, it is provided that the frame is attached to a gate circuit board by gluing or soldering.

In a further advantageous further development of the method according to the present invention for manufacturing a power module bridge, it is provided that the one or more flexible printed circuit boards be attached after a frame has been mounted on the gate circuit board.

In a further advantageous further development of the method according to the present invention for manufacturing a power module bridge, it is provided that the power module bridge is attached to a cooling element.

According to the present invention, a use for manufacturing a power module bridge in a vehicle according to a third aspect of the present invention is provided, wherein the power module bridge is used to convert current from direct current to alternating current.

The solution according to the present invention includes that effective insensitivity to thermomechanical loads is achieved by covering the power modules installed inside the power module bridge with gel. The risk of cracking is moreover avoided completely by eliminating the molding of the power module.

The solution according to the present invention also includes an uncomplicated method that enables integration into existing power module bridges without interface modification, wherein the necessary molding of the power modules is eliminated. Eliminating the need for molding the power modules moreover makes it possible to save costs.

The solution according to the present invention is further advantageously characterized in that, in contrast to encapsulated power modules that are installed in a power module bridge, no or only minimal mechanical stress is exerted on the power electronics of the power module in the presented solution. This is achieved by eliminating the need for an encasement by molding the power module and surrounding it with gel.

### BRIEF DESCRIPTION OF THE DRAWINGS

Example embodiments of the present invention are explained in more detail with reference to the figures and the following description.

FIG. 1 shows a schematic plan view onto an embodiment example of a power module according to the present invention.

FIG. 1.1 shows a schematic illustration of a power module according to an example embodiment of the present invention in the z-direction.

FIG. 2 shows a schematic plan view onto an embodiment example of a power module according to the present invention with a flexible printed circuit board.

FIG. 3 shows a schematic perspective view of a power module bridge, according to an example embodiment of the present invention.

FIG. 3.1 shows a schematic plan view onto a gate circuit board with a frame, according to an example embodiment of the present invention.

FIG. 4 shows a schematic perspective view of a power module bridge with connecting elements, according to an example embodiment of the present invention.

FIG. 5 shows a schematic cross-sectional view of a power module bridge, according to an example embodiment of the present invention.

FIG. 6 shows a schematic illustration of a method for manufacturing a power module bridge, according to an example embodiment of the present invention.

### DETAILED DESCRIPTION OF EXAMPLE EMBODIMENTS

In the following description of the embodiments of the present invention, identical or similar elements are denoted by identical reference signs, wherein a repeated description of these elements is omitted in individual cases. The figures show the subject matter of the present invention only schematically.

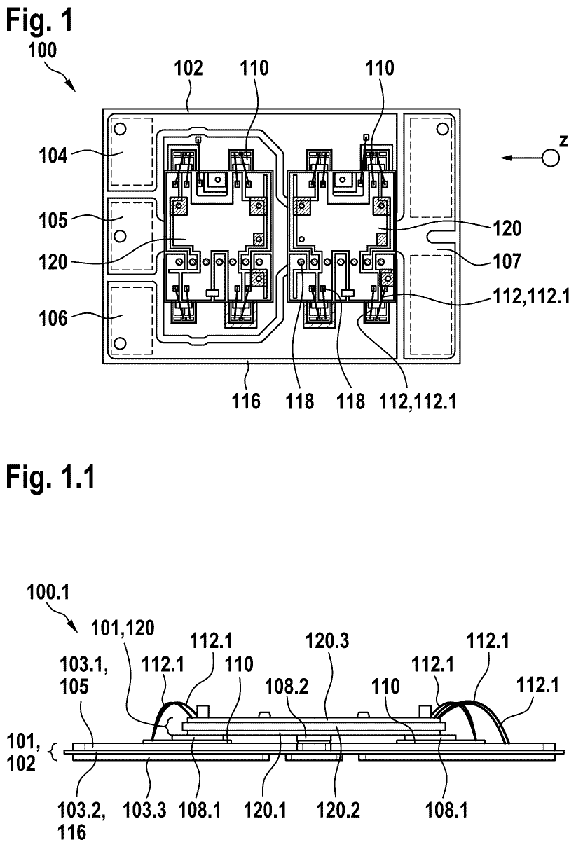

In the schematic illustration according to FIG. 1, the embodiment example of a power module 100 according to the present invention includes a circuit carrier 102 comprising an insulating layer 116 on which a first conductor structure 104, a second conductor structure 105, a third conductor structure 106 and a fourth conductor structure 107 are disposed, wherein all of the conductor structures 104, 105, 106 and 107 have a conductor shape. The conductor structures 104 and 105 each comprise at least two semiconductor switches 110, while the third conductor structure 106 comprises four semiconductor switches 110. As can be seen in FIG. 1, the power module 100 includes two connection boards 120 and the connection boards 120 comprise a plurality of contact elements 118. FIG. 1 also shows a power connection 112 of the semiconductor switches 110 with the connection boards 120 by means of power bonding wires 112.1. The power connection 112 can be established by means of a material-locking connection using power bonding wires 112.1, for example, in particular by soldering. The power bonding wires 112.1 include wires made of gold, aluminum or copper, for instance. FIG. 1 further includes a directional arrow pointing in z-direction.

In the schematic illustration according to FIG. 1.1, the embodiment example includes an illustration of a power module 100 according to FIG. 1 in z-direction 100.1. FIG. 1.1 also includes a circuit carrier 102, wherein the circuit carrier 102 comprises a three-layered layer of material 101 consisting of a first outer circuit carrier layer 103.1, a middle circuit carrier layer 103.2, and a second outer circuit carrier layer 103.3. FIG. 1.1 also includes a connection board 120, wherein the connection board 120 includes a three-layered layer of material 101 comprising a first outer connection board layer 120.1, a middle connection board layer 120.2, and a second outer connection board layer 120.3. Three spacers 108.1 and 108.2 are shown in FIG. 1.1 as well, wherein an outer spacer 108.1 is formed above the semiconductor switch 110 and a spacer 108.2 is shown between the circuit carrier 102 and the connection board 120.

In the event of thermally induced heating, for example of one or more components such as the semiconductor switch 110, the connection board 120 and the circuit carrier 102 of a power module 100, the thermal load on these components is effectively dissipated by the spacers 108.1 and 108.2. A spacer 108.1 and 108.2 can be made of ceramic, plastic or metal, for example. The type of spacers 108.1 and 108.2 in a power module 100 can vary; for instance depending on size, power and environment. The spacers 108.1 and 108.2 are connected to power module components such as a semiconductor switch 110, a connection board 120 and a circuit carrier 102 by sintering, for instance. Semiconductor switches 110 are also connected to the circuit carrier 102 by sintering.

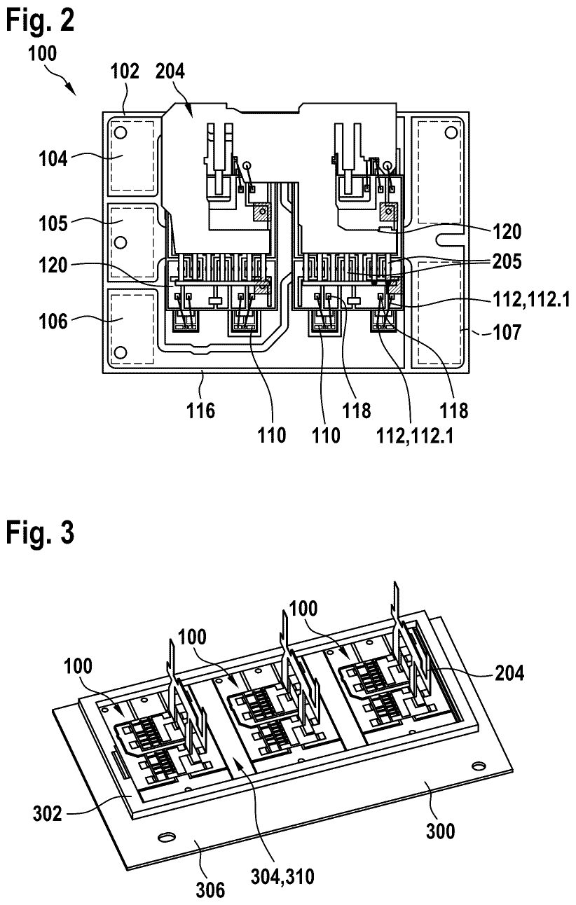

In the schematic illustration according to FIG. 2, the embodiment example of a power module 100 according to the present invention includes a circuit carrier 102 comprising an insulating layer 116 on which a first conductor structure 104, a second conductor structure 105, a third conductor structure 106 and a fourth conductor structure 107 are disposed, wherein all of the conductor structures 104, 105, 106 and 107 have a conductor shape. As can be seen in FIG. 2, the power module 100 includes two connection boards 120 and the connection boards 120 comprise a plurality of contact elements 118. FIG. 2 also shows a power connection 112 of the semiconductor switches 110 with the connection boards 120 by means of power bonding wires 112.1. Also shown in FIG. 2 is a flexible printed circuit board 204 with fourteen conductor tracks 205, wherein seven conductor tracks 205 on each connection board 120 are connected to contact elements 118 of a connection board 120, for example via a solder connection.

The electrical contact between the flexible printed circuit board 204 and the connection board 120 can alternatively be established via solder connections or adhesive connections or plug connections. A contact element 118 of a connection board 120 can alternatively also be configured as a socket or plug.

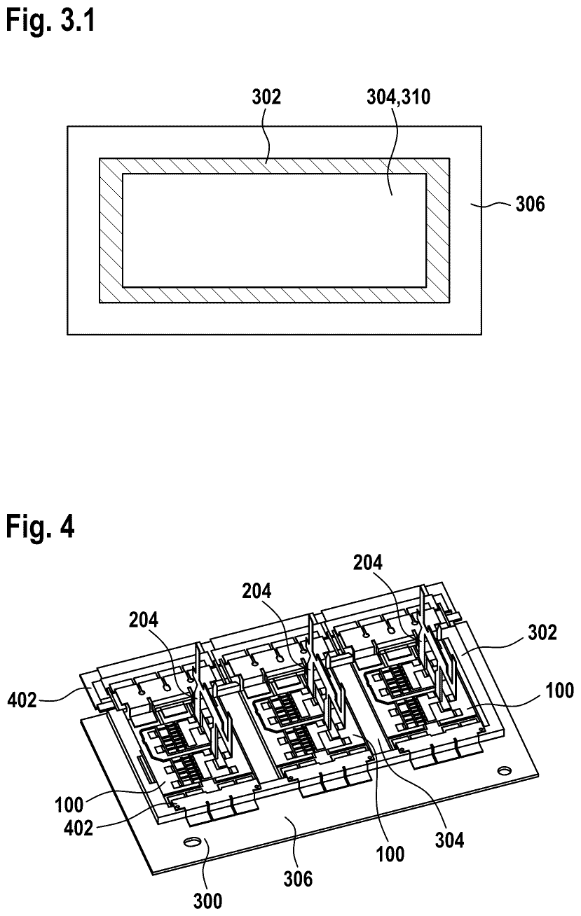

FIG. 3 shows a schematic perspective view of a power module bridge 300 comprising a gate circuit board 306, a frame 302, wherein the frame 302 is made of plastic, for example, and three power modules 100 which each have a flexible printed circuit board 204 attached to it and are positioned within the frame 302. FIG. 3 shows an example of an alignment of the unattached portion of the flexible printed circuit board 204, wherein the unattached portion of the flexible printed circuit board 204 is aligned horizontally, or at 90°, to the attached portion of the flexible printed circuit board 204 or to the power modules 100.

Alternatively, the alignment of the flexible printed circuit board 204 can be adapted to the environment. FIG. 3 also shows a region 304 to be filled with gel 502. The region 304 to be filled with gel 502 is inside the volume 310 enclosed by the frame 302.

An enclosed volume 310 can be affected by the dimensions of a frame 302, for instance, which can be accomplished, for example, by determining the length, width and depth dimensions of the power modules 100 to be built inside the frame 302. A frame 302 preferably includes a frame height that is greater than the overall height of a power module 100 and its electronic components, such as the connection boards 120 and the power bonding wires 112.1.

The schematic illustration in FIG. 3.1 shows a plan view onto a gate circuit board 306 and a frame 302. FIG. 4 furthermore shows a region 304 or enclosed volume 310 (in plan view) to be filled with gel 502. A frame 302 can, for instance, be mounted on a gate circuit board 306 in any position wherein the positioning is varied according the requirements of the application, for example, in an electric vehicle. A frame 302 is connected to a gate circuit board 306 in a material-locking manner, for example. Alternatively, a frame 302 can be connected to a gate circuit board 306 by screwing, bolting, using clips or by means of holding chambers. The assembly variant can be adapted depending on the size and shape of a frame 302, the mechanical stress, the required stability and the assembly method. The thickness of the frame 302, too, can be varied according to the requirements of the application.

FIG. 4 shows a schematic perspective view of a power module bridge 300 comprising a gate circuit board 306, comprising connecting elements 402, comprising a frame 302, wherein the frame 302 is made of plastic, for example, and comprising three power modules 100 which each have a flexible printed circuit board 204 attached to it and are positioned within the frame 302. FIG. 4 shows an example of an alignment of the unattached portion of the flexible printed circuit board 204, wherein the unattached portion of the flexible printed circuit board 204 is aligned horizontally, or at 90°, to the attached portion of the flexible printed circuit board 204 or to the power modules 100.

Alternatively, the alignment of the flexible printed circuit board 204 can be adapted to the environment. FIG. 3 also shows a region 304 to be filled with gel 502. The region 304 to be filled with gel 502 is inside the volume 310 enclosed by the frame 302. A connecting element 402 is connected to the conductor structure 104, 105, 106 via the frame 302. The connecting elements 402 are busbars, for example, which in particular include a material with high conductivity and have a larger cross-section in order to facilitate current flow and minimize resistance.

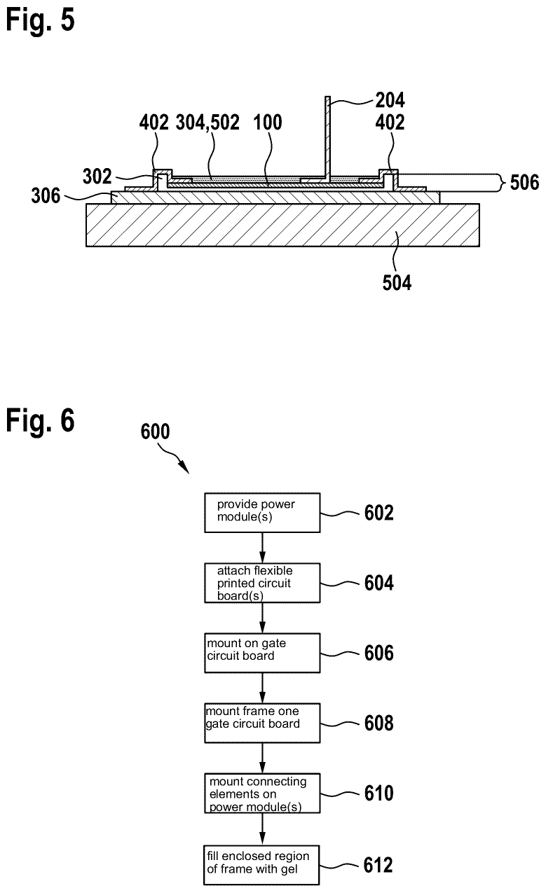

The schematic illustration in FIG. 5 shows a cross-sectional view of a power module bridge 300 on a cooling element 504. The cross-sectional view shows a section through a gate circuit board 306, the frame 302, wherein a frame 302 has a frame height 506, connecting elements 402, a power module 100 and a flexible printed circuit board 204. A region 304 to be filled with gel 502 can be seen in the cross-sectional view as well. FIG. 5 shows that the gel 502 filled in the frame 302 completely surrounds all of the electronic components. The alignment of a flexible printed circuit board 204 is shown in the cross-section of a power module bridge 300 as well, and it can be seen that the portion of a flexible printed circuit board 204 attached to the power module 100 is completely surrounded by the gel 502.

As can be seen from FIG. 6, the illustrated embodiment example of a method 600 according to the present invention for manufacturing a power module bridge 300 comprises a first step of providing 602 one or more power modules 100, a second step of attaching 604 the one or more flexible printed circuit boards 204 to the one or more power modules 100, a third step of mounting 606 the one or more power modules 100 on the gate circuit board 306, a fourth step of mounting 608 a frame 302 on the gate circuit board 306 around the one or more power modules 100, a fifth step of mounting 610 the one or more connecting elements 402 on the one or more power modules 100, and a sixth step of filling 612 the enclosed region 304 of a frame 302 with a gel 502.

The one or more power modules 100 can be attached to the cooling element 504 by soldering, for instance, and the frame 302 can then be attached around the one or more power modules 100 by gluing.

The present invention is not limited to the embodiment examples described here and the aspects highlighted therein. Rather, within the range of the present invention, a large number of modifications are possible which lie within the abilities of a person skilled in the art.

What is claimed is:

1. A power module bridge, comprising:
one or more power modules, each including:
i. one or more circuit carriers which include at least three layers of material, wherein a middle circuit carrier layer includes an insulating material, a first outer circuit carrier layer and a second outer circuit carrier layer include an electrically conductive material, wherein the first and second outer layers are configured as one or more conductor structures,
ii. one or more semiconductor switches,
iii. one or more connection boards including at least three layers of material, wherein a middle connection board layer includes an insulating material, a first outer connection board layer and a second outer connection board layer include an electrically conductive material, wherein the one or more connection boards include one or more contact elements,
iv. one or more flexible printed circuit boards, and
v. one or more spacers;
a gate circuit board;
a frame with lateral boundaries and with an upwardly and/or downwardly exposed region, wherein a volume enclosed by the frame is filled with a gel; and
one or more connecting elements;
wherein one or more of the circuit carriers, one or more of the semiconductor switches, one or more of the spacers, and one or more of the connection boards are connected to one another via a sintered connection.

2. The power module bridge according to claim 1, wherein one or more conductor tracks of the one or more flexible printed circuit boards are attached to the contact elements, a portion of each flexible printed circuit board is attached to one or more of the connection boards with a material-locking connection, and a remaining portion of the flexible printed circuit board is positioned perpendicular to the attached portion of the flexible printed circuit board.

3. The power module bridge according to claim 1, wherein the one or more power modules are positioned inside the frame.

4. The power module bridge according to claim 1, wherein the frame has a variable frame height.

5. The power module bridge according to claim 3, wherein the gel completely convers the one or more power modules.

6. The power module bridge according to claim 1, wherein the gel is a silicone gel.

7. A method for manufacturing a power module bridge including one or more power modules, a gate circuit board, a frame, a gel, and one or more connecting elements, wherein the method comprises the following steps:
a. providing the one or more power modules;
b. attaching one or more flexible printed circuit boards to the one or more power modules;
c. mounting the one or more power modules on the gate circuit board;
d. mounting the frame on the gate circuit board around the one or more power modules;
e. mounting the one or more connecting elements on the one or more power modules, wherein the one or more connecting elements are mounted such that each connecting element is also attached to the gate circuit board via the frame; and
f. filling a region enclosed by the frame with the gel.

8. The method according to claim 7, wherein the one or more power modules are attached to the gate circuit board by a material-locking connection.

9. The method according to claim 7, wherein the frame is attached to the gate circuit board by gluing or soldering.

10. The method according to claim 7, wherein the attaching of the one or more flexible printed circuit boards takes place after mounting the frame on the gate circuit board.

11. The method according to claim 7, wherein the power module bridge is attached to a cooling element.

12. The power module bridge according to claim 1, wherein the power module bridge is situated in a vehicle, and wherein the power module bridge is used to convert current from direct current to alternating current.
